(19) United States
(12) Patent Application Publication
(10) Pub. No.: US 2016/0342048 A1
(43) Pub. Date: Nov. 24, 2016

(54) THIN FILM TRANSISTOR ARRAY SUBSTRATE, LIQUID CRYSTAL PANEL AND LIQUID CRYSTAL DISPLAY DEVICE

(71) Applicant: SHENZHEN CHINA STAR OPTOELECTRONICS TECHNOLOGY CO., LTD., Shenzhen, Guangdong (CN)

(72) Inventor: Qiuping HUANG, Shenzhen, Guangdong (CN)

(73) Assignee: Shenzhen China Star Optoelectronics Technology Co., Ltd., Shenzhen, Guangdong (CN)

(21) Appl. No.: 14/425,043

(22) PCT Filed: Jan. 13, 2015
(86) PCT No.: PCT/CN2015/070606

§ 371 Date: Mar. 1, 2015

(30) Foreign Application Priority Data
Dec. 31, 2014 (CN) 201410856582.3

(51) Int. Cl. G02F 1/1362; H01L 27/12; G02F 1/1343; G02F 1/1368; G02F 1/1335; G02F 1/1345

(52) U.S. Cl. CPC G02F 1/136209; G02F 1/133514; G02F 1/1345; G02F 1/134309; G02F 1/136286; G02F 1/1368; G02F 1/136227; H01L 27/124; H01L 27/1248; G02F 2201/123; G02F 2201/121

(57) ABSTRACT

The disclosure relates to a thin film transistor array substrate, a liquid crystal panel having the same and a liquid crystal display device having the panel. The thin film transistor array substrate comprises a first substrate, scan lines and data lines arranged on the first substrate, and pixel regions defined by the scan lines crossing with the data lines, each of which comprising a thin film transistor and a pixel electrode arranged on the thin film transistor. A metal light-shielding layer formed between the thin film transistor and the pixel region comprises a first light-shielding region disposed between the source/drain terminal and the pixel electrode connected to the source/drain terminal through the first light-shielding region, a second light-shielding region disposed on the source layer, and a third light-shielding region disposed on the scan lines and the data lines. All of the light-shielding regions are separated with each other.

### BACKGROUND

1. Technical Field

The disclosure is related to liquid crystal display technology field, and more particular to a thin film transistor array substrate, a liquid crystal panel and a liquid crystal display device.

2. Related Art

A Liquid Crystal Display (LCD) is a thin and flat display device. The liquid crystal panel is an important part of a liquid crystal display.

Refer to FIGS. 1 to 3. The common used liquid crystal panel comprises an array substrate 1 and a color filter substrate 2 arranged oppositely to the array substrate 1, and a liquid crystal layer 3 disposed between the array substrate 1 and the color filter substrate 2. The array substrate 1 comprises a first substrate 11, scan lines 12 and data lines 13 on the first substrate 11, and pixel regions 14 defined by the scan lines 12 crossing with the data lines 13. The pixel region 14 comprises a thin film transistor 14a and a pixel electrode 14b on the thin film transistor 14a. The gate terminal 141 of the thin film transistor 14a electrically connects with the scan line 12. One of the source/drain terminals connects with the scan line 13 and the other source/drain terminal electrically connects with the pixel electrode 14b. The color filter substrate 2 comprises a second substrate 21 and a photoresist unit 22 array disposed on the second substrate 21. A black matrix 23 is disposed between two photoresist units 22.

The black matrix 22 on the color filter substrate 2 corresponds to the region of the scan line 12 and the data line 13, and the thin film transistor 14a on the array substrate 1 to prevent the light leakage between two pixel regions, which may affect the display quality. Because a distance exists between the array substrate 1 and the color filter substrate 2, it is required for the black matrix 22 to cover a larger area to prevent the light leakage. Thus the aperture ratio is reduced.

Further, no shelter is arranged above the source layer 144 of the thin film transistor 14a on the array substrate 1 as shown in FIG. 1. Thus the light may irradiate on the source layer 144 to generate photogenerated carriers such that the performance of the display is reduced.

### SUMMARY

In order to solve the problem existing in the current technology, one embodiment of the disclosure provides a thin film transistor array substrate. A metal light-shielding layer is formed on the thin film transistor array for light-shielding to replace the traditional black matrix disposed on the color filter substrate. The metal light-shielding layer may shelter the light from irradiating on the source layer of the thin film transistor. The display quality of the display device is increased.

The disclosure provides the following embodiments.

A thin film transistor array substrate comprises a first substrate, scan lines and data lines arranged on the first substrate, and pixel regions defined by the scan lines crossing with the data lines. Each of the pixel regions comprises a thin film transistor and a pixel electrode arranged on the thin film transistor. The thin film transistor comprises a gate terminal formed on the first substrate and electrically connected to the scan lines, a source layer formed on the gate terminal, and a source/drain terminal electrically connected to the source layer, one end of the source/drain terminal connected to the data lines, and the other end of the source/drain terminal connected to the pixel electrode. A metal light-shielding layer is formed between the thin film transistor and the pixel electrode, the metal light-shielding layer comprising a first light-shielding region, a second light-shielding region and third light-shielding region, all of which separated with each other; the first light-shielding region disposed between the source/drain terminal and the pixel electrode, the pixel electrode connected to the source/drain terminal through the first light-shielding region; the second light-shielding region disposed on the source layer; the third light-shielding region disposed on the scan lines and the data lines.

In one embodiment, a first dielectric insulation layer having a first through hole is formed on the thin film transistor, the metal light-shielding layer disposed on the first dielectric insulation layer, the first light-shielding region connected to the source/drain terminal through the first through hole; a second dielectric insulation layer having a second through hole is formed on the metal light-shielding layer, the pixel electrode disposed on the second dielectric insulation layer, the pixel electrode connected to the first light-shielding region through the second through hole.

In one embodiment, the metal light-shielding layer is a single layer or a multilayer made of black metal material.

In one embodiment, the metal material is molybdenum.

In one embodiment, a gate insulation layer is formed on the gate terminal, the source/drain terminal and the source layer disposed on the gate insulation layer.

The disclosure further provides a liquid crystal panel comprising an array substrate, a color filter substrate arranged oppositely to the array substrate, and a liquid crystal layer disposed between the array substrate and the color filter substrate. The array substrate is the thin film transistor array substrate. The color filter substrate comprises a second substrate and a photoresist unit array formed on the second substrate.

In one embodiment, a common electrode layer is formed between the color filter substrate and the liquid crystal layer.

In one embodiment, the photoresist unit array comprises a red photoresist, green photoresist and a blue photoresist.

The disclosure further provides a liquid crystal display device comprises a liquid crystal panel and a backlight module arranged oppositely to the liquid crystal panel, the backlight module providing light to the liquid crystal panel to display an image. The liquid crystal panel is the liquid crystal panel as stated above.

Comparing with the current technology, the thin film transistor array substrate according to the embodiment of the disclosure may shelter the light through disposing a metal light-shielding layer on the thin film transistor array to replace the traditional black matrix arranged on the color filter substrate. Because the metal light-shielding layer is disposed on the array substrate, the region requiring sheltering may be aligned much better and is closer to the metal light-shielding layer. Thus the required area is smaller (compared with the black matrix formed on the color filter substrate of the current technology) to cover the region requiring sheltering. The pixel region may have a higher aperture ratio. Besides, the metal light-shielding layer may shelter the light from irradiating on the source layer of the thin film transistor. The display quality of the display device is increased.

### BRIEF DESCRIPTION OF THE DRAWINGS

The above and other exemplary aspects, features and advantages of certain exemplary embodiments of the present disclosure will be more apparent from the following description taken in conjunction with the accompanying drawings, in which:

FIG. 1 is a schematic structure of a liquid crystal panel of the prior art;

FIG. 2 is the structure of the array substrate of the liquid crystal panel as shown in FIG. 1;

FIG. 3 is the structure of the color filter substrate of the liquid crystal panel as shown in FIG. 1;

FIG. 4 is a schematic structure of a liquid crystal panel according to the embodiment of the disclosure;

FIG. 5 is the cross section view of the array substrate according to the embodiment of the disclosure;

FIG. 6 is the top view of the array substrate according to the embodiment of the disclosure;

FIG. 7 is the structure of the color filter substrate according to the embodiment of the disclosure; and

FIG. 8 is the structure of the liquid crystal display device according to the embodiment of the disclosure.

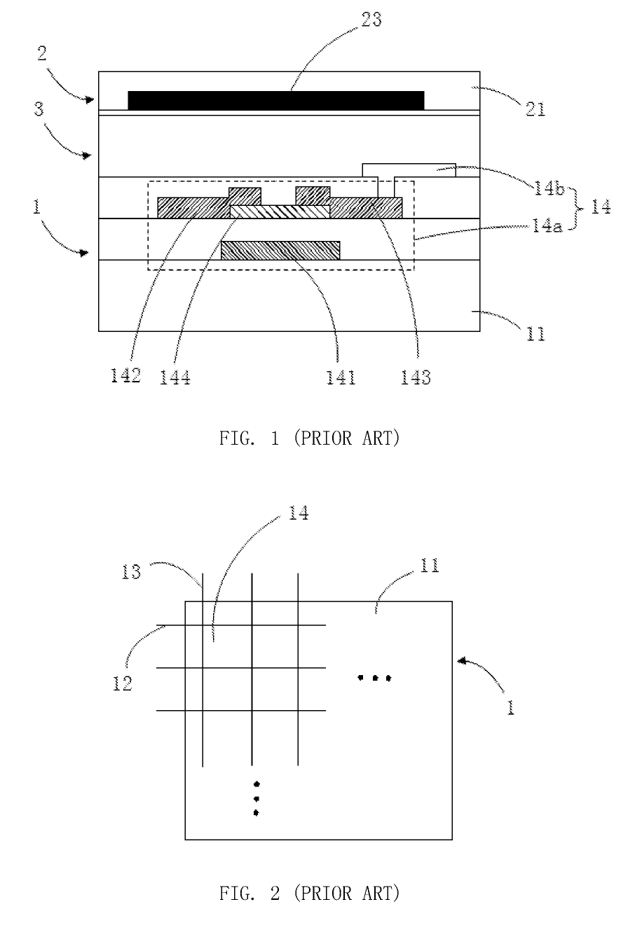

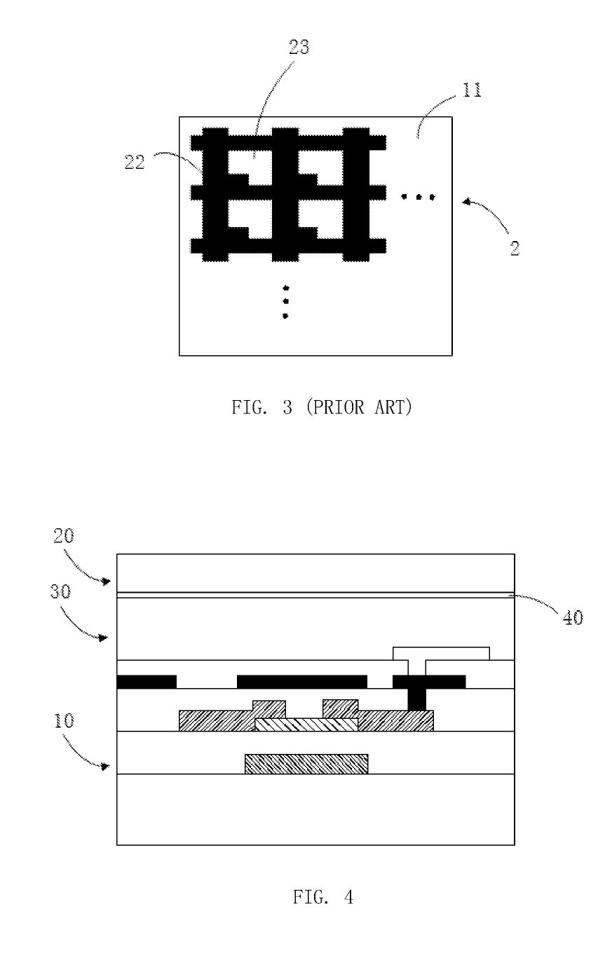

### DETAILED DESCRIPTION

As stated above, the purpose of the disclosure is to provide a thin film transistor array substrate and a liquid crystal panel having the same to solve the problem that a larger black matrix area is required to dispose on the color filter substrate due to the cell gap to cover the region for prevent light leakage and the problem that the aperture ration of the display is reduced. A higher aperture ratio of the pixel region of the liquid crystal panel may be obtained by disposing a metal light-shielding layer on the thin film transistor array to replace the traditional black matrix on the color filter. Besides, the metal light-shielding layer may shelter the light from irradiating on the source layer of the thin film transistor. The display quality of the display device is increased.

The following description with reference to the accompanying drawings is provided to explain the exemplary embodiments of the disclosure in details. It is apparent that the embodiments are merely some examples of the disclosure, rather than all examples of the disclosure. Based on the embodiments of the disclosure, all other embodiments attainable by those skilled in the art without inventive endeavor belong to the protection scope of the disclosure.

As shown in FIG. 4, the liquid crystal panel of this embodiment comprises an array substrate 10, a color filter substrate 20 and a liquid crystal layer 30 disposed between the array substrate 10 and the color filter substrate 20. A common electrode layer 40 is further disposed between the color filter substrate 20 and the liquid crystal layer 30.

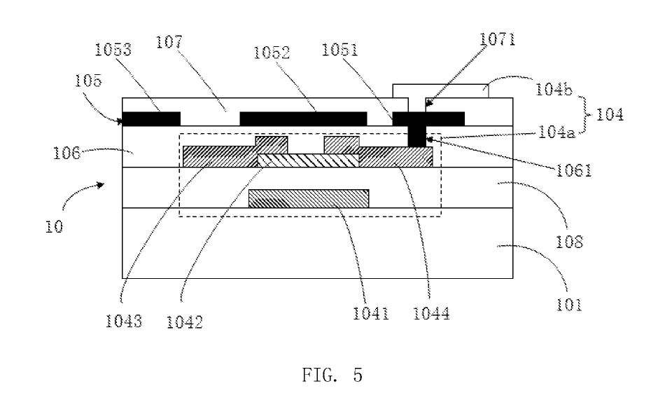

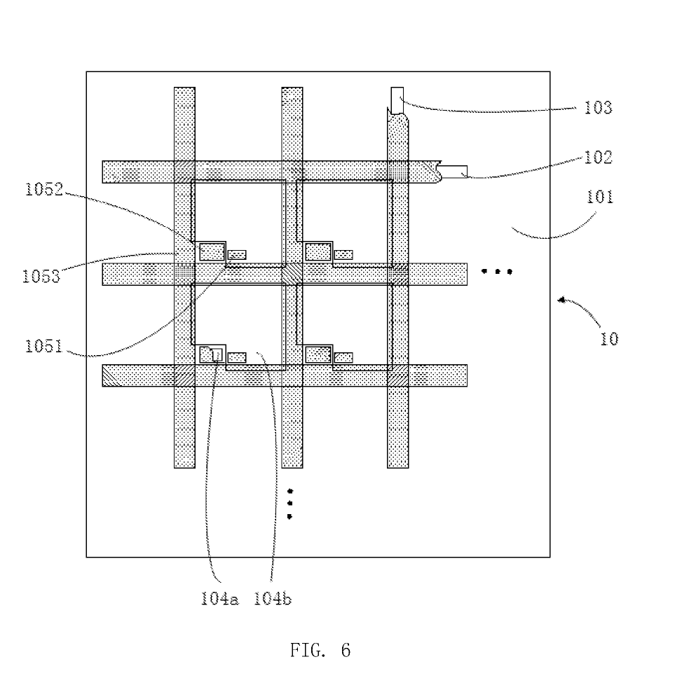

Refer to FIG. 5 and FIG. 6. The array substrate 10 is a thin film transistor array substrate. The array substrate 10 comprises a first substrate 10, scan lines 102 and data lines 103 formed on the first substrate 101, pixel regions 104 defined by the scan lines 102 crossing with the data lines 103. The pixel regions 104 comprise a thin film transistor 104a and a pixel electrode 104b on the thin film transistor 104a.

Specifically, the thin film transistor 104a is disposed close to the intersection between the scan line 102 and the date line 103. As shown in FIG. 5, the thin film transistor 104a comprises a gate terminal 1041 formed on the first substrate 101, a source layer 1042, and a source/drain terminal 1043, 1044 electrically connected to the source layer 1042. The gate terminal electrically connects with the scan line 102. One end of the source/drain terminal 1043, 1044 electrically connects with the scan line 102, and the other end electrically connects to the pixel electrode 104b. Furthermore, a gate insulation layer 108 is formed on the gate terminal 1041. The source/drain terminal 1043, 1044 and the source layer 1042 are disposed on the gate insulation layer 108.

In the array substrate 10 of the embodiment, a metal light-shielding layer 105 is formed between the thin film transistor 104a and the pixel electrode 104b. The metal light-shielding layer 105 comprising a first light-shielding region 1051, a second light-shielding region 1052 and a third light-shielding region 1053, all of which separated with each other. As shown in FIG. 6, the first light-shielding region 1051 is disposed between the source/drain terminal 1043, 1044 and the pixel electrode 104b. The pixel electrode 104b is connected to the source/drain terminal 1043, 1044 through the first light-shielding region 1051. The second light-shielding region 1052 is disposed on the source layer 1042. The third light-shielding region 1053 is disposed on the scan lines 102 and the data lines 103. Specifically, as shown in FIG. 5, a first dielectric insulation layer 106 having a first through hole 1061 is formed on the thin film transistor 104a. The metal light-shielding layer 105 is disposed on the first dielectric insulation layer 106. The first light-shielding region is connected to the source/drain terminal 1043, 1044 through the first through hole 1061. A second dielectric insulation layer 107 having a second through hole 1071 is formed on the metal light-shielding layer 105. The pixel electrode 104b is disposed on the second dielectric insulation layer 107. The pixel electrode 104b is connected to the first light-shielding region 1051 through the second through hole 1071.

After the first dielectric insulation layer 106 is finished, the metal light-shielding layer 105 may be obtained on the first dielectric insulation layer 106 through PVD process. Then the metal light-shielding layer 105 may be divided into the first light-shielding region 1051, the second light-shielding region 1052, and the third light-shielding region 1053 that are separated with each other by etching process. The metal light-shielding layer 105 is a single layer or a multilayer made of black metal material. The metal material is molybdenum.

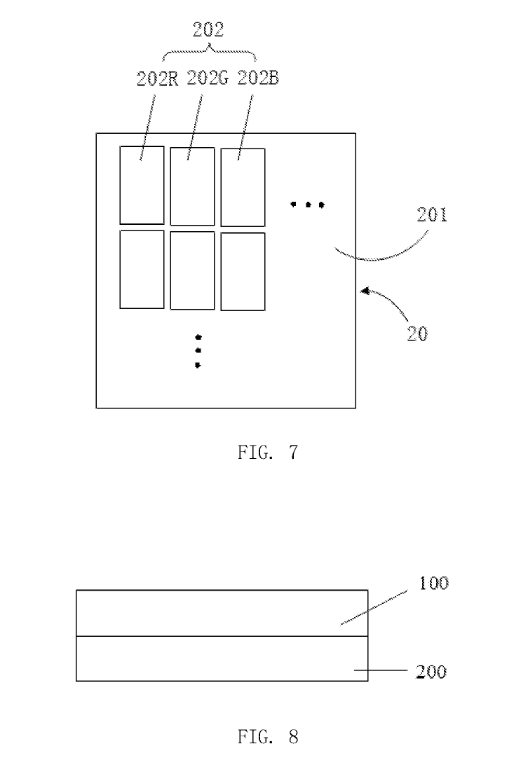

The metal light-shielding layer 105 covers the region above the non-display region of the scan line 102, the data line 103 and the thin film transistor 104a to shelter the light. Correspondingly, the process for the black matrix on the color filter substrate 20 in the liquid crystal panel may be canceled. As shown in FIG. 7, the color filter substrate 20 in the liquid crystal panel comprises a second substrate 201 and the photoresist unit 202 array formed on the second substrate 201. The photoresist unit 201 array comprises a red photoresist 202R, a green photoresist 202G, and a blue photoresist 202B. Because the metal light-shielding layer is disposed on the array substrate 10, the region requiring sheltering may be aligned much better and is closer to the metal light-shielding layer. Thus the required area is smaller (compared with the black matrix formed on the color filter substrate of the current technology) to cover the region requiring sheltering. The pixel region 104 may have a higher aperture ratio.

Further, the second light-shielding region 1052 is disposed on the source layer 1042. The light may be sheltered from irradiating on the source layer 1042 of the thin film transistor 104a. The photogenerated carriers may be reduced such that the working status of the thin film transistor 104a is more stable. The display quality of the display device is increased.

Furthermore, a second dielectric insulation layer 107 is disposed between the pixel electrode 104b and the metal light-shielding layer 105. The pixel electrode 104b is merely conductive with the third light-shielding layer 1053 through the second through hole 1071. The pixel electrode 104b is insulated from the first light-shielding region 1051 and the second light-shielding region 1052. Therefore, a pixel electrode 104b with larger area may be designed. As shown in FIG. 6, the pixel electrode 104b may be extended above the third light-shielding area 1053 (above the scan line 102 and the data line 103). The area of the pixel region is increased and the aperture ratio is further increased.

The embodiment further provides a liquid crystal display device. As shown in FIG. 8, the liquid crystal display device comprises a liquid crystal panel 100 and a backlight module 200. The liquid crystal panel 100 and the backlight module 200 are disposed oppositely. The backlight module 200 provides light sauce to the liquid crystal panel 100 to display an image. The liquid crystal panel 100 adopts the liquid crystal panel as provided in the previous embodiments.

Although the present disclosure is illustrated and described with reference to specific embodiments, those skilled in the art will understand that many variations and modifications are readily attainable without departing from the spirit and scope. Such variations and modifications should also be regarded as the protection of the disclosure.

What is claimed is:

1. A thin film transistor array substrate, comprising:
a first substrate;
scan lines and data lines arranged on the first substrate; and
pixel regions defined by the scan lines crossing with the data lines;
wherein each of the pixel regions comprises a thin film transistor and a pixel electrode arranged on the thin film transistor;
wherein the thin film transistor comprises a gate terminal formed on the first substrate and electrically connected to the scan lines, a source layer formed on the gate terminal, and a source/drain terminal electrically connected to the source layer, one end of the source/drain terminal connected to the data lines, and the other end of the source/drain terminal connected to the pixel electrode;
wherein a metal light-shielding layer is formed between the thin film transistor and the pixel electrode, the metal light-shielding layer comprising a first light-shielding region, a second light-shielding region and third light-shielding region, all of which separated with each other; the first light-shielding region disposed between the source/drain terminal and the pixel electrode, the pixel electrode connected to the source/drain terminal through the first light-shielding region; the second light-shielding region disposed on the source layer; the third light-shielding region disposed on the scan lines and the data lines.

2. The thin film transistor array substrate according to claim 1, wherein a first dielectric insulation layer having a first through hole is formed on the thin film transistor, the metal light-shielding layer disposed on the first dielectric insulation layer, the first light-shielding region connected to the source/drain terminal through the first through hole; a second dielectric insulation layer having a second through hole is formed on the metal light-shielding layer, the pixel electrode disposed on the second dielectric insulation layer, the pixel electrode connected to the first light-shielding region through the second through hole.

3. The thin film transistor array substrate according to claim 2, wherein the metal light-shielding layer is a single layer or a multilayer made of black metal material.

4. The thin film transistor array substrate according to claim 3, wherein the metal material is molybdenum.

5. The thin film transistor array substrate according to claim 2, wherein a gate insulation layer is formed on the gate terminal, the source/drain terminal and the source layer disposed on the gate insulation layer.

6. A liquid crystal panel, comprising:
an array substrate;
a color filter substrate arranged oppositely to the array substrate, the color filter substrate comprising a second substrate and a photoresist unit array formed on the second substrate; and
a liquid crystal layer disposed between the array substrate and the color filter substrate;
Wherein the array substrate is a thin film transistor array substrate, comprising a first substrate; scan lines and data lines arranged on the first substrate; and pixel regions defined by the scan lines crossing with the data lines;
wherein each of the pixel regions comprises a thin film transistor and a pixel electrode arranged on the thin film transistor;
wherein the thin film transistor comprises a gate terminal formed on the first substrate and electrically connected to the scan lines, a source layer formed on the gate terminal, a source/drain terminal electrically connected to the source layer, one end of the source/drain terminal connected to the data lines, and the other end of the source/drain terminal connected to the pixel electrode;
wherein a metal light-shielding layer is formed between the thin film transistor and the pixel electrode, the metal light-shielding layer comprising a first light-shielding region, a second light-shielding region and third light-shielding region, all of which separated with each other; the first light-shielding region disposed between the source/drain terminal and the pixel electrode, the pixel electrode connected to the source/drain terminal through the first light-shielding region; the second light-shielding region disposed on the source layer; the third light-shielding region disposed on the scan lines and the data lines.

7. The liquid crystal panel according to claim 6, wherein a first dielectric insulation layer having a first through hole is formed on the thin film transistor, the metal light-shielding layer disposed on the first dielectric insulation layer, the first light-shielding region connected to the source/drain terminal through the first through hole; a second dielectric insulation layer having a second through hole is formed on the metal light-shielding layer, the pixel electrode disposed on the second dielectric insulation layer, the pixel electrode connected to the first light-shielding region through the second through hole.

8. The liquid crystal panel according to claim 7, wherein the metal light-shielding layer is a single layer or a multilayer made of black metal material.

9. The liquid crystal panel according to claim 8, wherein the metal material is molybdenum.

10. The liquid crystal panel according to claim 7, wherein a gate insulation layer is formed on the gate terminal, the source/drain terminal and the source layer disposed on the gate insulation layer.

11. The liquid crystal panel according to claim 6, wherein a common electrode layer is formed between the color filter substrate and the liquid crystal layer.

12. The liquid crystal panel according to claim 6, wherein the photoresist unit array comprises a red photoresist, green photoresist and a blue photoresist.

13. A liquid crystal display device, comprises:
a liquid crystal panel;
a backlight module arranged oppositely to the liquid crystal panel, the backlight module providing light to the liquid crystal panel to display an image;
wherein the liquid crystal panel comprises an array substrate; a color filter substrate arranged oppositely to the array substrate, the color filter substrate comprising a second substrate and a photoresist unit array formed on the second substrate; and a liquid crystal layer disposed between the array substrate and the color filter substrate;
wherein the array substrate is a thin film transistor array substrate, comprising a first substrate; scan lines and data lines arranged on the first substrate; and pixel regions defined by the scan lines crossing with the data lines;
wherein each of the pixel regions comprises a thin film transistor and a pixel electrode arranged on the thin film transistor;
wherein the thin film transistor comprises a gate terminal formed on the first substrate and electrically connected to the scan lines, a source layer formed on the gate terminal, a source/drain terminal electrically connected to the source layer, one end of the source/drain terminal connected to the data lines, and the other end of the source/drain terminal connected to the pixel electrode;
wherein a metal light-shielding layer is formed between the thin film transistor and the pixel electrode, the metal light-shielding layer comprising a first light-shielding region, a second light-shielding region and third light-shielding region, all of which separated with each other; the first light-shielding region disposed between the source/drain terminal and the pixel electrode, the pixel electrode connected to the source/drain terminal through the first light-shielding region; the second light-shielding region disposed on the source layer; the third light-shielding region disposed on the scan lines and the data lines.

14. The liquid crystal display device according to claim 13, wherein a first dielectric insulation layer having a first through hole is formed on the thin film transistor, the metal light-shielding layer disposed on the first dielectric insulation layer, the first light-shielding region connected to the source/drain terminal through the first through hole; a second dielectric insulation layer having a second through hole is formed on the metal light-shielding layer, the pixel electrode disposed on the second dielectric insulation layer, the pixel electrode connected to the first light-shielding region through the second through hole.

15. The liquid crystal display device according to claim 14, wherein the metal light-shielding layer is a single layer or a multilayer made of black metal material.

16. The liquid crystal display device according to claim 15, wherein the metal material is molybdenum.

17. The liquid crystal display device according to claim 14, wherein a gate insulation layer is formed on the gate terminal, the source/drain terminal and the source layer disposed on the gate insulation layer.

18. The liquid crystal display device according to claim 13, wherein a common electrode layer is formed between the color filter substrate and the liquid crystal layer.

19. The liquid crystal display device according to claim 13, wherein the photoresist unit array comprises a red photoresist, green photoresist and a blue photoresist.
